(19) United States
(12) Patent Application Publication
(10) Pub. No.: US 2024/0284724 A1
(43) Pub. Date: Aug. 22, 2024

(54) DISPLAY DEVICE AND METHOD OF MANUFACTURING THE DISPLAY DEVICE

(71) Applicant: Samsung Display Co., Ltd., Yongin-si (KR)

(72) Inventor: Hyunseung Lee, Yongin-si (KR)

(73) Assignee: Samsung Display Co., Ltd., Yongin-si (KR)

(21) Appl. No.: 18/485,585

(22) Filed: Oct. 12, 2023

(30) Foreign Application Priority Data
Feb. 20, 2023 (KR) 10-2023-0022422

(51) Int. Cl. H10K 59/126; G09G 3/3233; H10K 59/12

(52) U.S. Cl. CPC H10K 59/126; G09G 3/3233; H10K 59/1201; G09G 2300/0842

(57) ABSTRACT

A method of manufacturing a display device includes forming a lower structure including a substrate, forming, on the lower structure, an organic layer including a base resin and silica particles surface-treated with a liquid-repellent material, performing a pre-baking process by heating the organic layer, performing an exposure process by irradiating a light source to the organic layer, and performing a development process to form a light-shielding layer by removing a portion of the organic layer. In the development process, the silica particles surface-treated with the liquid-repellent material are removed from the organic layer.

### CROSS REFERENCE TO RELATED APPLICATION(S)

This application claims priority to and benefits of Korean Patent Application No. 10-2023-0022422 under 35 U.S.C. § 119, filed on Feb. 20, 2023, in the Korean Intellectual Property Office (KIPO), the entire contents of which are incorporated herein by reference.

### BACKGROUND

### 1. Technical Field

Embodiments relate to a display device and a method of manufacturing the same, and more particularly, to a display device with improved visibility and a method of manufacturing the display device.

### 2. Description of the Related Art

Organic light-emitting display devices are self-illuminating and do not require separate light sources, unlike liquid crystal display devices, and weights and thicknesses of the organic light-emitting display devices may be reduced. Also, organic light-emitting display devices have high-quality characteristics, such as low power consumption, high brightness, high response speed, and the like.

### SUMMARY

The disclosure provides a display device having improved visibility by reducing external light reflection. However, the scope of the disclosure is not limited thereto.

Additional aspects will be set forth in part in the description which follows and, in part, will be apparent from the description, or may be learned by practice of embodiments of the disclosure.

According to an embodiment, a method of manufacturing a display device may include forming a lower structure including a substrate, forming, on the lower structure, an organic layer including a base resin and silica particles surface-treated with a liquid-repellent material, performing a pre-baking process by heating the organic layer, performing an exposure process by irradiating light onto the organic layer, and performing a development process to form a light-shielding layer by removing a portion of the organic layer, wherein, in the development process, the silica particles surface-treated with the liquid-repellent material may be removed from the organic layer.

In the pre-baking process, the silica particles surface-treated with the liquid-repellent material may be moved to an upper portion of the organic layer.

An upper surface of the light-shielding layer may include a plurality of protrusions.

The plurality of protrusions of the light-shielding layer may be irregularly arranged.

At least some of the plurality of protrusions of the light-shielding layer may have different widths in a direction.

A gap between adjacent ones of the plurality of protrusions of the light-shielding layer may be in a range of about 10 nm to about 60 nm.

Sizes of the silica particles surface-treated with the liquid-repellent material may be in a range of about 10 nm to about 60 nm.

The liquid-repellent material may include a fluorine-based material.

The base resin may include a photosensitive organic material and a coloring agent.

The base resin may include a negative photosensitive organic material.

The pre-baking process may be performed for a period in a range of about 100 seconds to about 200 seconds at a temperature in a range of about 80° C. to about 90° C.

The method may further include performing a post-baking process by heating the light-shielding layer.

The post-baking process may be performed for a period in a range of about 50 minutes to about 70 minutes at a temperature in a range of about 80° C. to about 90° C.

The lower structure may include a display layer disposed on the substrate and including a light-emitting diode and a thin-film transistor electrically connected to the light-emitting diode, a low-reflection layer disposed on the display layer and including an inorganic material, a thin-film encapsulation layer disposed on the low-reflection layer, and a touch sensor layer disposed on the thin-film encapsulation layer and including a conductive layer.

The method may further include forming a color filter layer on the light-shielding layer.

According to an embodiment, a display device includes a first light-emitting diode, a second light-emitting diode, and a third light-emitting diode, which are disposed on a substrate and implement emission areas by emitting light of different wavelengths, a low-reflection layer disposed on the first light-emitting diode, the second light-emitting diode, and the third light-emitting diode and including an inorganic material, and a light-shielding layer disposed on the low-reflection layer and including an opening corresponding to the emission area, wherein an upper surface of the light-shielding layer may have an uneven shape including a plurality of protrusions, and the plurality of protrusions may be irregularly arranged.

At least some of the plurality of protrusions may have different widths in a direction.

A gap between adjacent ones of the plurality of protrusions may be in a range of about 10 nm to about 60 nm.

The display device may further include a color filter layer including a first color filter, a second color filter, and a third color filter, which respectively correspond to the first light-emitting diode, the second light-emitting diode, and the third light-emitting diode and are arranged in the openings of the light-shielding layer.

The display device may further include a reflection control layer covering the light-shielding layer and the openings of the light-shielding layer and integrally formed on the first light-emitting diode, the second light-emitting diode, and the third light-emitting diode.

### BRIEF DESCRIPTION OF THE DRAWINGS

The above and other aspects, features, and advantages of embodiments of the disclosure will be more apparent from the following description taken in conjunction with the accompanying drawings, in which:

FIG. 1 is a schematic perspective view of a display device according to an embodiment;

FIG. 2 is a schematic diagram of an equivalent circuit of a pixel circuit and a display element electrically connected to the pixel circuit included in a pixel of a display device according to an embodiment;

FIG. 3 is a schematic cross-sectional view of a display device according to an embodiment;

FIG. 4A is a schematic plan view of a portion of pixel arrangements in a display area;

FIG. 4B is a schematic plan view of a portion of pixel arrangements in a display area;

FIG. 5A is a schematic cross-sectional view of a portion of a display device according to an embodiment;

FIG. 5B is a schematic enlarged view of region ‘B’ of FIG. 5A;

FIG. 6 is a schematic cross-sectional view of a portion of a display device according to another embodiment; and

FIGS. 7 to 12 are schematic cross-sectional views illustrating a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

As the disclosure allows for various changes and numerous embodiments, particular embodiments will be shown in the drawings and described in detail in the written description. The attached drawings for illustrating embodiments of the disclosure are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.” Throughout the disclosure, the expression “at least one of a, b, or c” indicates only a, only b, only c, both a and b, both a and c, both b and c, all of a, b, and c, or variations thereof.

The terminology used herein is for the purpose of describing particular embodiments and is not intended to be limiting. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Further, the x-axis, the y-axis, and the z-axis are not limited to three axes of a rectangular coordinate system, such as the x, y, and z axes, and may be interpreted in a broader sense. For example, the x-axis, the y-axis, and the z-axis may be perpendicular to one another, or may represent different directions that are not perpendicular to one another.

Spatially relative terms, such as “under,” “lower,” “above,” “upper,” and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the example term “below” can encompass both an orientation of above and below. Furthermore, the apparatus may be otherwise oriented (e.g., rotated 90 degrees or at other orientations), and, as such, the spatially relative descriptors used herein interpreted accordingly.

Embodiments of the disclosure will be described more fully with reference to the accompanying drawings, like reference numerals in the drawings denote like elements, and repeated descriptions thereof will not be provided.

It will be understood that although the terms “first,” “second,” etc. may be used herein to describe various elements, these elements should not be limited by these terms, and these elements are only used to distinguish one element from another. Thus, a first element discussed below could be termed a second element without departing from the teachings of the disclosure.

As used herein, the singular forms “a,” “an,” and “the” are intended to include the plural forms as well, unless the context clearly indicates otherwise.

It will be further understood that the terms “comprises,” “includes,” “comprising,” and/or “including” used herein specify the presence of stated features, integers, steps, operations, elements, components, and/or groups thereof, but do not preclude the presence or addition of one or more other features or components.

It will be understood that when a layer, region, or component is referred to as being connected to another layer, region, or component, it can be directly or indirectly connected to the other layer, region, or component. For example, when a layer, region, or component is referred to as being electrically connected to another layer, region, or component, it can be directly or indirectly electrically connected to the other layer, region, or component. Also, when a component is described herein to “connect” another component to the other component or to be “connected to” other components, the components may be connected to each other as separate elements, or the components may be integral with each other.

It will be understood that when a layer, region, or element is referred to as being “on” or “connected to” another layer, region, or element, it can be directly or indirectly on or connected to the other layer, region, or element. For example, intervening layers, regions, or elements may be present. When, however, an element or layer is referred to as being “directly on,” “directly formed on,” or “directly connected to” another element or layer, there are no intervening elements or layers present. To this end, the term “connected” may refer to physical, electrical, and/or fluid connection, with or without intervening elements.

Unless otherwise specified, the illustrated embodiments are to be understood as providing example features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

Sizes of elements in the drawings may be exaggerated or reduced for convenience of explanation. In other words, since sizes and thicknesses of elements in the drawings are arbitrarily illustrated for convenience of explanation, the disclosure is not limited thereto.

Further, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

When a certain embodiment may be implemented differently, a specific process order may be performed differently from the described order. For example, two consecutively described processes may be performed substantially at the same time or performed in an order opposite to the described order.

The display surface may be parallel to a surface defined by the x-axis and the y-axis. A normal direction of the display surface, i.e., a thickness direction of the display device 1, may indicate the z-axis. In this specification, an expression of “when viewed from a plane or in a plan view” may represent a case when viewed in the z-axis. Hereinafter, a front surface (or a top surface) and a rear surface (or a bottom surface) of each of layers or units may be distinguished by the z-axis. However, directions indicated by the x-axis, the y-axis, and the z-axis may be a relative concept, and converted with respect to each other, e.g., converted into opposite directions.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

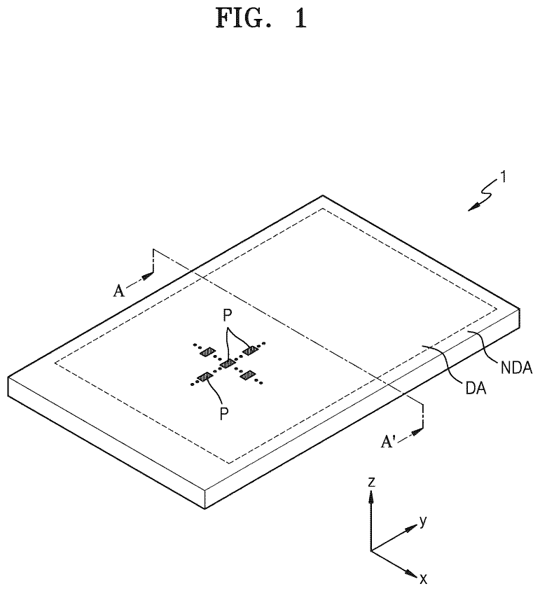

FIG. 1 is a schematic perspective view of a display device 1 according to an embodiment.

In an embodiment, a display device 1 may display a moving image or a still image and may be used as a display screen of various products, for example, a portable electronic device, such as a mobile phone, a smartphone, a tablet Personal Computer (PC), a mobile communication terminal, a personal digital assistant, an e-book terminal, a Portable Multimedia Player (PMP), a navigation device, an Ultra Mobile PC (UMPC), or the like, a television (TV), a laptop, a monitor, a billboard, Internet of Things (IoT) device, and the like.

Also, in an embodiment, the display device 1 may be used in a wearable device, such as a smartwatch, a watch phone, an eyewear display, a head-mounted display (HMD), or the like. Also, in an embodiment, the display device 1 may be used as a display in an instrument cluster of a vehicle, a Center Information Display (CID) mounted on a center fascia or a dashboard of a vehicle, a room mirror display replacing a side-view mirror of a vehicle, a car headrest monitor provided for rear-seat entertainment, or the like. For convenience of explanation, FIG. 1 shows that the display device 1 is used as a smartphone.

Referring to FIG. 1, the display device 1 may include a display area DA and a non-display area NDA disposed adjacent to the display area DA. The non-display area NDA may be disposed outside (or surround) the display area DA. FIG. 1 shows that a shape of the display area DA is substantially a rectangle in a plan view, but the disclosure is not limited thereto. The display area DA may have various shapes, such as a circle, an oval, a polygon, and the like in a plan view.

The display area DA may be a portion in which images are displayed and multiple sub-pixels P are arranged. Each of the sub-pixels P may include a light-emitting diode, such as an organic light-emitting diode OLED or the like. For example, sub-pixel P may emit light, such as red light, green light, blue light, or white light.

In the display area DA, images may be provided using the light emitted from the sub-pixels P. In the specification, the sub-pixel P may include an emission area where one of red light, green light, blue light, and white light is emitted, as described above.

The non-display area NDA may be an area where no sub-pixels P are arranged, and images are not provided. In the non-display area NDA, a terminal connected to a printed circuit board or a driver IC including power supply lines and driving circuitry for driving the sub-pixels P and the like may be arranged.

Hereinafter, an organic light-emitting display device is described as the display device 1 according to an embodiment. However, the display device 1 is not limited thereto. For example, the display device 1 may be an inorganic light-emitting display device (or an inorganic

EL display device), a quantum dot light-emitting display device, or the like. For example, an emission layer included in a light-emitting diode of the display device 1 may include an organic material or an inorganic material. Quantum dots may be located in a path of light emitted from the emission layer.

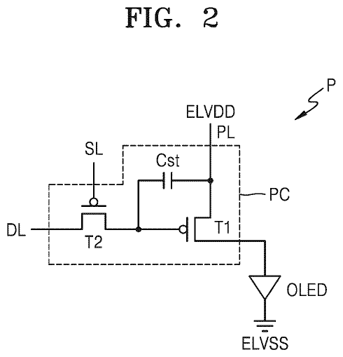

FIG. 2 is a schematic diagram of an equivalent circuit of a pixel circuit and a display element electrically connected to the pixel circuit included in a pixel P of a display device 1 according to an embodiment.

Referring to FIG. 2, an organic light-emitting diode OLED, which is a display element, may be electrically connected to the pixel circuit PC. The pixel circuit PC may include a first thin-film transistor T1, a second thin-film transistor T2, and a storage capacitor Cst. For example, the organic light-emitting diode OLED may emit red light, green light, or blue light or emit red light, green light, blue light, or white light.

The second thin-film transistor T2 may be a switching thin-film transistor, may be electrically connected to a scan line SL and a data line DL, and may transmit, to the first thin-film transistor T1, a data voltage that is input through the data line DL, according to a switching voltage that is input through the scan line SL. The storage capacitor Cst may be electrically connected to the second thin-film transistor T2 and a driving power line PL and may store a voltage corresponding to a difference between a voltage from the second thin-film transistor T2 and a first power voltage ELVDD provided to the driving power line PL.

The first thin-film transistor T1 may be a driving thin-film transistor, may be electrically connected to the driving power line PL and the storage capacitor Cst, and may control a driving current flowing to the organic light-emitting diode OLED from the driving power line PL, according to the voltage stored in the storage capacitor Cst. The organic light-emitting diode

OLED may emit light having a brightness (e.g., a certain or selectable brightness) corresponding to the driving current. An opposite electrode (e.g., a cathode) of the organic light-emitting diode OLED may receive a second power voltage ELVSS.

FIG. 2 shows that the pixel circuit PC includes two thin-film transistors T1 and T2 and one storage capacitor Cst, but the disclosure is not limited thereto, and the number of thin-film transistors and the number of storage capacitors may vary according to the design of the pixel circuit PC.

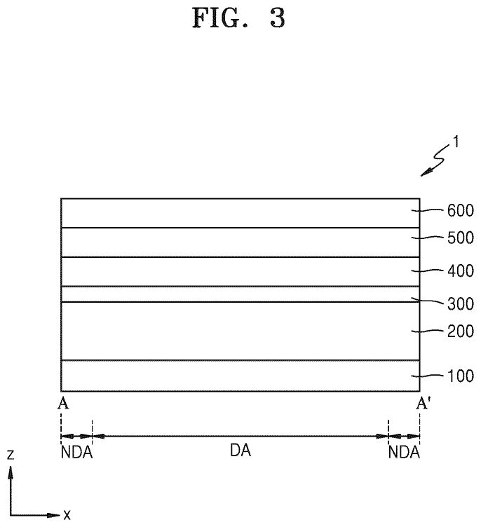

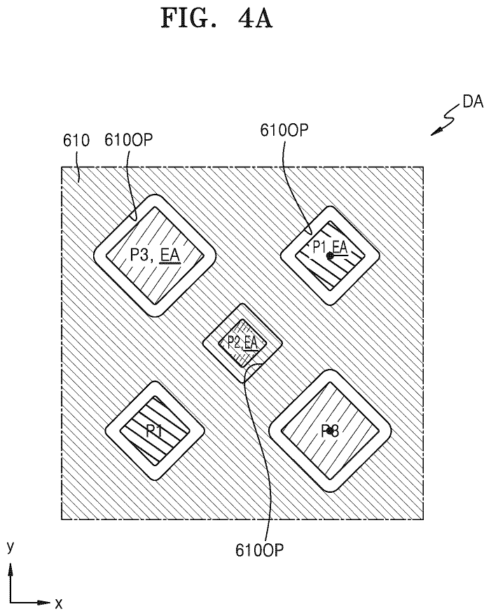

FIG. 3 is a schematic cross-sectional view of the display device 1 according to an embodiment, taken along line A-A′ of FIG. 1.

Referring to FIG. 3, the display device 1 may include a substrate 100, a display layer 200, a low-reflection layer 300, a thin-film encapsulation layer 400, a touch sensor layer 500, and an anti-reflection layer 600.

The substrate 100 may include glass, a polymer resin, or the like. For example, the polymer resin may include polyether sulfone, polyacrylate, polyetherimide, polyethylene naphthalate, polyethylene terephthalate, polyphenylene sulfide, polyarylate, polyimide, polycarbonate, cellulose acetate propionate, the like, or a combination thereof. The substrate 100 including a polymer resin may be flexible, rollable, or bendable. The substrate 100 may have a multilayered structure that includes a layer including a polymer resin, an inorganic layer (not shown), or the like.

The display layer 200 may include an organic light-emitting diode OLED as a display element, for example, a light-emitting diode, a thin-film transistor electrically connected to the organic light-emitting diode OLED, and insulating layers arranged between the organic light-emitting diode OLED and the thin-film transistor.

The low-reflection layer 300 may be disposed on the display layer 200, and the thin-film encapsulation layer 400 may be disposed on the low-reflection layer 300. For example, the display layer 200 and/or the low-reflection layer 300 may be sealed by the thin-film encapsulation layer 400. The thin-film encapsulation layer 400 may include at least one inorganic layer and at least one organic layer.

In an embodiment, the display device may include an encapsulation substrate (not shown) including glass instead of the thin-film encapsulation layer 400. The encapsulation substrate may be disposed on the display layer 200, and the display layer 200 may be disposed between the substrate 100 and the encapsulation substrate. A gap may exist between the encapsulation substrate and the display layer 200 and may be filled with fillers.

The touch sensor layer 500 may be disposed on the thin-film encapsulation layer 400. The touch sensor layer 500 may sense an external input, e.g., a touch from an object, such as a finger, a stylus pen, or the like, and display device 1 may obtain coordinate information corresponding to a touch location. The touch sensor layer 500 may include a touch electrode and trace lines electrically connected to the touch electrode. The touch sensor layer 500 may detect an external input in a mutual cap manner, a self-cap manner, or the like.

In an embodiment, the touch sensor layer 500 may be formed (e.g., directly formed) on the thin-film encapsulation layer 400. In another embodiment, after separately formed, the touch sensor layer 500 may adhere onto the thin-film encapsulation layer 400 by an adhesive layer, such as an optically clear adhesive (OCA) or the like.

The anti-reflection layer 600 may be disposed on the touch sensor layer 500. The anti-reflection layer 600 may reduce a reflectivity of light (external light) that is incident on the display device 1.

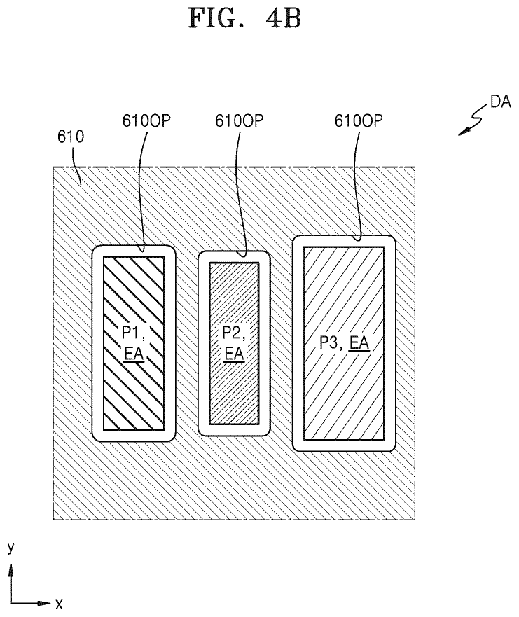

FIGS. 4A and 4B are schematic plan views of a portion of pixel arrangement (or sub-pixel arrangements) in a display area DA.

Referring to FIGS. 1 and 4A, a display device 1 may include pixels, and each of the pixels may include a first pixel P1, a second pixel P2, and a third pixel P3 which emit different colors of light. For example, the first pixel P1, the second pixel P2, and the third pixel P3 may emit red light, green light, and blue light, respectively. However, the disclosure is not limited thereto. Various modifications may be made to the pixels, for example, the first pixel P1, the second pixel P2, and the third pixel P3 may emit blue light, green light, and red light, respectively.

The first pixel P1, the second pixel P2, and the third pixel P3 may each have a polygonal shape such as a square in a plan view. In the specification, a polygonal shape and a square shape include a shape with rounded vertices. In another embodiment, the shape of each of the first pixel P1, the second pixel P2, and the third pixel P3 may be a circle, an oval, or the like in a plan view.

Sizes of the first pixel P1, the second pixel P2, and the third pixel P3 may be different from each other in a plan view. For example, an area of the second pixel P2 may be less than areas of the first pixel P1 and the third pixel P3, and the area of the first pixel P1 may be greater than the area of the third pixel P3 in a plan view. However, the disclosure is not limited thereto, and various modifications may be made to the pixels. For example, the sizes of the first pixel P1, the second pixel P2, and the third pixel P3 may be substantially the same in a plan view.

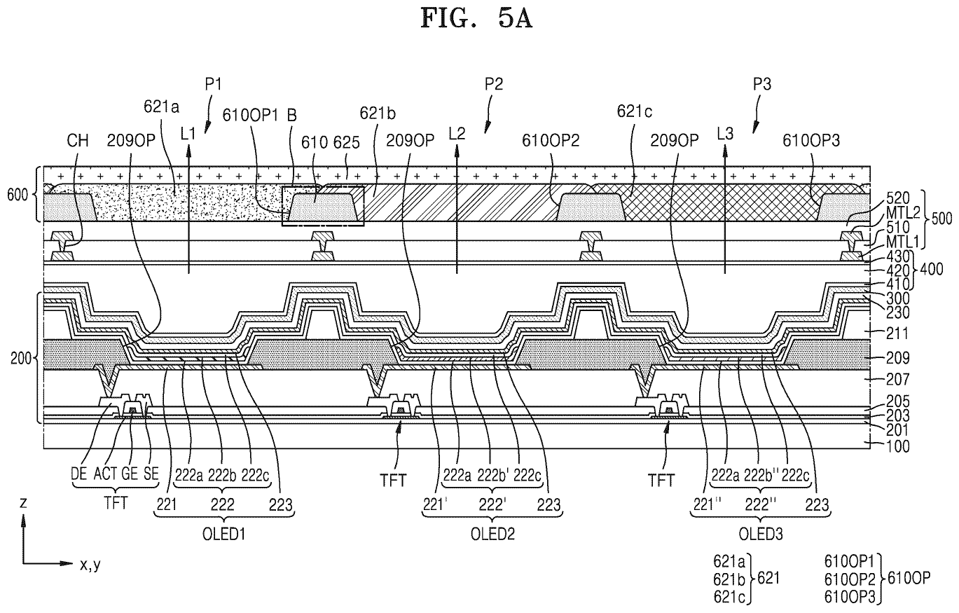

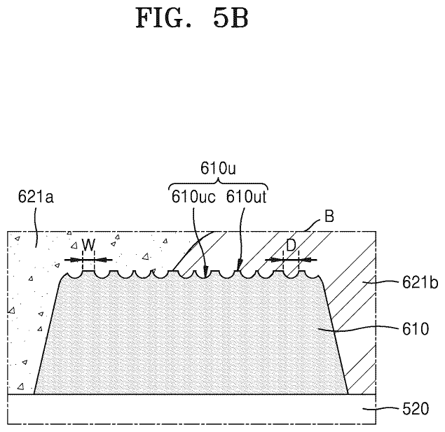

In the specification, the sizes of the first pixel P1, the second pixel P2, and the third pixel P3 may be sizes of emission areas EA of display elements implementing each of the pixels, and the emission areas EA may be defined by openings 209OP of a pixel-defining layer (see, e.g., 209 of FIG. 5A).

A light-shielding layer 610 disposed on the display layer 200 may include an opening 610OP corresponding to each of the pixels. The opening 610OP may be a region where a portion of the light-shielding layer 610 is removed, and light emitted from the display element may be directed outwards through the openings 610OP. A body of the light-shielding layer 610 may include a material that absorbs external light, and a visibility of the display device 1 may be improved.

In a plan view, the openings 610OP of the light-shielding layer 610 may surround each of the first to third pixel P1, P2, and P3. In an embodiment, a shape of the opening 610OP of the light-shielding layer 610 may be a square with rounded edges in a plan view. An area of the opening 610OP of the light-shielding layer 610, which corresponds to each of the first to third pixels P1, P2, and P3, may be greater than the area of each of the first to third pixels P1 to P3 in a plan view. However, the disclosure is not limited thereto. The area of each opening 610OP of the light-shielding layer 610 and the area of each of the first to third pixels P1, P2, and P3 may be substantially the same.

As shown in FIG. 4A, the first pixel P1, the second pixel P2, and the third pixel P3 may be arranged (or disposed) in a pixel arrangement having a PenTile® structure in a plan view.

However, the disclosure is not limited thereto. As shown in FIG. 4B, for example, the first pixel P1, the second pixel P2, and the third pixel P3 may be arranged in a stripe form in a plan view. In another embodiment, the first pixel P1, the second pixel P2, and the third pixel P3 may be arranged in various pixel arrangement structures, such as a mosaic structure, a delta structure, and the like.

FIG. 5A is a schematic cross-sectional view of a portion of a display device 1 according to an embodiment. FIG. 5B is a schematic enlarged view of region ‘B’ of FIG. 5A. With reference to FIGS. 5A and 5B, a configuration of the display device 1 according to an embodiment is described in detail according to a stack order.

Referring to FIGS. 5A and 5B, the display device 1 may include the substrate 100, the display layer 200, the low-reflection layer 300, the thin-film encapsulation layer 400, the touch sensor layer 500, and the anti-reflection layer 600.

The display layer 200 may be disposed on the substrate 100. The display layer 200 may include a first organic light-emitting diode OLED1, a second organic light-emitting diode OLED2, a third organic light-emitting diode OLED3, and a thin-film transistor TFT and may further include a buffer layer 201, a gate insulating layer 203, an interlayer insulating layer 205, a planarization layer 207, a pixel-defining layer 209, and a spacer 211, which are insulating layers. In an embodiment, the display layer 200 may further include a capping layer 230 disposed on the first to third organic light-emitting diode OLED1, OLED2, and OLED3.

The buffer layer 201 may be disposed on the substrate 100, reduce or prevent penetration of foreign materials, moisture, or external air from a bottom of the substrate 100, and provide a flat surface to the substrate 100. The buffer layer 201 may include an inorganic material, such as oxide, nitride, or the like, an organic material, or a compound of organic and inorganic materials and may have a single-layer structure or a multilayered structure including the inorganic material, the organic material, or the organic and inorganic materials. A barrier layer (not shown) may be further included between the substrate 100 and the buffer layer 201, the barrier layer preventing the penetration of external air or the like. The buffer layer 201 may include silicon oxide (SiO₂), silicon nitride (SiNₓ), or the like.

The thin-film transistor TFT may be disposed on the buffer layer 201. The thin-film transistor TFT may include a semiconductor layer ACT, a gate electrode GE, a source electrode

SE, and a drain electrode DE. The thin-film transistor TFT may be electrically connected to each of the first to third organic light-emitting diodes OLED1, OLED2, and OLED3 (hereinafter, an organic light-emitting diode OLED) and drive the organic light-emitting diode OLED.

The semiconductor layer ACT may be disposed on the buffer layer 201 and include polysilicon. In another embodiment, the semiconductor layer ACT may include amorphous silicon. In another embodiment, the semiconductor layer ACT may include oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), zinc (Zn), and the like. The semiconductor layer ACT may include a channel area and source and drain areas doped with an impurity.

The gate electrode GE, the source electrode SE, and the drain electrode DE may include a conductive material. The gate electrode GE may include at least one of molybdenum (Mo), aluminum (Al), copper (Cu), and Ti. For example, the gate electrode GE may be a single Mo layer or have a three-layer structure including a Mo layer, an Al layer, and a Mo layer. The source electrode SE and the drain electrode DE may each include at least one material selected from the group consisting of Cu, Ti, and Al. For example, the source electrode SE and the drain electrode DE may each have a three-layer structure including a Ti layer, an Al layer, and a Ti layer.

A gate insulating layer 203 including an inorganic material, such as SiO₂, SiNₓ , silicon oxynitride (SiON) and/or the like, may be arranged between the semiconductor layer ACT and the gate electrode GE to insulate the semiconductor layer ACT from the gate electrode GE. The interlayer insulating layer 205 including an inorganic material, such as SiO₂, SiNₓ , SiON, and/or the like, may be disposed on the gate electrode GE, and the source electrode SE and the drain electrode DE may be disposed on the interlayer insulating layer 205. The insulating layers may be formed through Chemical Vapor Deposition (CVD), Atomic Layer Deposition (ALD), or the like, which may also be applied to below.

The planarization insulating layer 207 may be disposed on the thin-film transistor TFT. To provide a flat upper surface, the planarization layer 207 may be formed, and chemical mechanical polishing may be performed on the upper surface of the planarization layer 207. The planarization layer 207 may include a general-purpose polymer, such as photosensitive polyimide, polyimide, polystyrene (PS), polycarbonate (PC), benzocyclobutene (BCB), hexamethyldisiloxane (HMDSO), polymethylmethacrylate (PMMA), polystyrene (PS), or the like, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, the like, or any blend thereof. FIG. 5A shows that the planarization layer 207 is a single layer, but the planarization layer 207 may include multiple layers.

The first to third organic light-emitting diodes OLED1, OLED2, and OLED3 may be disposed on the planarization layer 207. The first organic light-emitting diode OLED1 may include a first pixel electrode 221, a first intermediate layer 222 including a first common layer 222a, a first emission layer 222b, and a second common layer 222c, and an opposite electrode 223. The second organic light-emitting diode OLED2 may include a second pixel electrode 221′, a second intermediate layer 222′ including a first common layer 222a, a second emission layer 222b′, and a second common layer 222c, and an opposite electrode 223. The third organic light-emitting diode OLED3 may include a third pixel electrode 221″, a third intermediate layer 222″ including a first common layer 222a, a third emission layer 222b″, and a second common layer 222c, and an opposite electrode 223. In an embodiment, the first to third organic light-emitting diodes OLED1, OLED2, and OLED3 may emit light having different wavelengths and each implement the emission areas EA.

Hereinafter, the description will be focused on the first organic light-emitting diode OLED1 included in the first pixel P1, and because a stacked structure of the second organic light-emitting diode OLED2 and the third organic light-emitting diode OLED3 and a stacked structure of the first organic light-emitting diode OLED1 may be substantially the same, repeated descriptions are omitted.

The first organic light-emitting diode OLED1 may include the first pixel electrode 221 (hereinafter, a pixel electrode 221), the first intermediate layer 222 (hereinafter, an intermediate layer 222), and the opposite electrode 223.

The pixel electrode 221 may be disposed on the planarization layer 207. The pixel electrode 221 may be arranged on each of the first to third pixels P1, P2, and P3. The pixel electrodes 221 each corresponding to adjacent pixels may be arranged apart from each other in an x-axis or a y-axis intersecting the x-axis.

The pixel electrode 221 may be a reflection electrode, and may include a reflection film including silver (Ag), magnesium (Mg), Al, platinum (Pt), palladium (Pd), gold (Au), nickel (Ni), neodymium (Nd), iridium (Ir), chromium (Cr), or a compound thereof. The pixel electrode 221 may include a transparent or translucent conductive layer formed on the reflection film.

The transparent or translucent conductive layer may include at least one material selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, the pixel electrode 221 may have a stacked structure of ITO/Ag/ITO.

The pixel-defining layer 209 may be disposed on the pixel electrode 221. The pixel-defining layer 209 may include an opening 209OP exposing a portion (e.g., a central portion) of each pixel electrode 221. The pixel-defining layer 209 may cover edges of the pixel electrode 221 and increase a distance between the edges of the pixel electrode 221 and the opposite electrode 223, thereby preventing arcs or the like from being generated on the edges of the pixel electrode 221.

The pixel-defining layer 209 may include an organic insulating material. In another embodiment, the pixel-defining layer 209 may include an inorganic insulating material, such as SiNₓ, SiON, or SiO₂ . In another embodiment, the pixel-defining layer 209 may include an organic insulating material and an inorganic insulating material. In an embodiment, the pixel-defining layer 209 may include a light-shielding material and may be black or the like. The light-shielding material may include carbon black, a carbon nanotube, resin or paste including a black dye or the like, metal particles such as Ni, Al, Mo, the like, and an alloy thereof, metal oxide particles (e.g., chromium oxide), metal nitride particles (e.g., chromium nitride), or the like. In case that the pixel-defining layer 209 includes a light-shielding material, external light reflection from metal structures disposed under the pixel-defining layer 209 may decrease. However, the disclosure is not limited thereto. In another embodiment, as shown in FIG. 5A, the pixel-defining layer 209 may not include a light-shielding material and may include an organic insulating material that is light-transmissive or the like.

The spacer 211 may be disposed on the pixel-defining layer 209. The spacer 211 may include an organic insulating material, such as polyimide or the like. In another embodiment, the spacer 211 may include an inorganic insulating material, such as SiNₓ, SiO₂ , or the like or may include an organic insulating material and an inorganic insulating material.

In an embodiment, the spacer 211 and the pixel-defining layer 209 may include a same material. The spacer 211 and pixel-defining layer 209 may be integrally formed in a mask process using a halftone mask. In an embodiment, the spacer 211 and the pixel-defining layer 209 may include different materials.

The intermediate layer 222 may be disposed on the pixel electrode 221 and the pixel-defining layer 209. The intermediate layer 222 may include the first common layer 222a, the emission layer 222b (for example, the first emission layer 222b), and the second common layer 222c.

The emission layer 222b may be arranged in the opening 209OP of the pixel-defining layer 209. The emission layer 222b may include an organic material including a fluorescent material, a phosphorescent material, or the like and may emit blue light, green light, or red light.

The organic material may be a low-molecular-weight organic material or a high-molecular-weight organic material. In another embodiment, the emission layer 222b may include an inorganic material including quantum dots. For example, the quantum dots may be crystals of a semiconductor compound and include a material that emits light of various wavelengths according to sizes of the crystals. The quantum dots may include, for example, a III-VI group semiconductor compound, a II-VI group semiconductor compound, a III-V group semiconductor compound, a III-VI group semiconductor compound, a I-III-VI group semiconductor compound, a IV-VI group semiconductor compound, a IV group elements or compound, the like, or a combination thereof.

The first common layer 222a may be disposed under the emission layer 222b, and the second common layer 222c may be disposed on the emission layer 222b. For example, the first common layer 222a may include a Hole Transport Layer (HTL) or include an HTL and a Hole Injection Layer (HIL). For example, the second common layer 222c may include an Electron Transport Layer (ETL) or include an ETL and an Electron Injection Layer (EIL). In an embodiment, the second common layer 222c may be omitted.

While the emission layer 222b is arranged on each pixel P1, P2, or P3 to correspond to the opening 209OP of the pixel-defining layer 209, the first and second common layers 222a and 222c may each be integrally formed to entirely cover the substrate 100. For example, each of the first and second common layers 222a and 222c may be integrally formed to entirely cover the display area DA of the substrate 100.

The opposite electrode 223 may be a cathode that is an electron injection electrode. The opposite electrode 223 may include a conductive material having a low work function. For example, the opposite electrode 223 may include a transparent (or translucent) layer including Ag, Mg, Al, Pt, Pd, Au, Ni, Nd, Ir, Cr, lithium (Li), calcium (Ca), ytterbium (Yb), the like, or an alloy thereof. For example, the opposite electrode 223 may include AgMg, AgYb, the like, or a combination thereof. In another embodiment, the opposite electrode 223 may further include a layer including ITO, IZO, ZnO, In₂O₃ , the like, or a combination thereof on the transparent (or translucent) layer. Layers from the pixel electrode 221 to the opposite electrode 223 may form the organic light-emitting diode OLED.

In an embodiment, the display device 1 may further include the capping layer 230 disposed on the organic light-emitting diode OLED. The capping layer 230 may improve an emission efficiency of the organic light-emitting diode OLED according to a principle of constructive interference. The capping layer 230 may include, for example, a material having a refractive index of greater than or equal to about 1.6 for light having a wavelength of about 589 nm.

The capping layer 230 may include an organic capping layer including an organic material, an inorganic capping layer including an inorganic material, or a compound capping layer including an organic material and an inorganic material. For example, the capping layer 230 may include a carbocyclic compound, a heterocyclic compound, an amine group-containing compound, porphine derivatives, phthalocyanine derivatives, naphthalocyanine derivatives, alkali metal complexes, alkali earth metal complexes, the like, or a combination thereof. The carbocyclic compound, the heterocyclic compound, and the amine group-containing compound may be optionally substituted with a substituent including oxygen (O), nitrogen (N), sulfur (S), selenium (Se), silicon (Si), fluorine (F), chlorine (Cl), bromine (Br), iodine (I), the like, or a combination thereof.

The low-reflection layer 300 may be disposed on the capping layer 230. Because the capping layer 230 may be disposed on the organic light-emitting diode OLED, the low-reflection layer 300 may be also disposed on the organic light-emitting diode OLED. The low-reflection layer 300 may include an inorganic material with low reflectivity, and in an embodiment, the low-reflection layer 300 may include a metal, a metal oxide, or the like. For example, the low-reflection layer 300 may include Yb, bismuth (Bi), cobalt (Co), Mo, Ti, Zr, Al, Cr, Nb, Pt, tungsten (W), In, Sn, iron (Fe), Ni, tantalum (Ta), manganese (Mn), Zn, Ge, Ag, Mg, Au, Cu, Ca, the like, or a combination thereof. For example, the low-reflection layer 300 may include SiO₂, titanium oxide (TiO₂), zirconium oxide (ZrO₂), tantalum oxide (Ta₂O₅), hafnium oxide (HfO₂), aluminum oxide (Al₂O₃), zinc oxide (ZnO), yttrium oxide (Y₂O₃), beryllium oxide (BeO), magnesium oxide (MgO), lead oxide (PbO₂), tungsten oxide (WO₃), SiNₓ, lithium fluoride (LiF), calcium fluoride (CaF₂), magnesium fluoride (MgF₂), cadmium sulfide (CdS), the like, or a combination thereof.

In an embodiment, an absorption coefficient k of an inorganic material included in the low-reflection layer 300 may be in a range of about 0.5 to about 4.0 (0.5≤k≤4.0). Also, the inorganic material included in the low-reflection layer 300 may have a refractive index n that is greater than or equal to about 1 (n≥1.0).

The low-reflection layer 300 may induce a destructive interference between light, which is incident to the display device 1, and light, which is reflected from metal arranged under the low-reflection layer 300, reducing the reflectivity of external light. Therefore, as the reflectivity of external light in the display device 1 is reduced by the low-reflection layer 300, the display quality and the visibility of the display device 1 may be improved.

FIG. 5A shows that the low-reflection layer 300 is disposed on the entire substrate 100 like the opposite electrode 223 and the capping layer 230, but the disclosure is not limited thereto. For example, the low-reflection layer 300 may be patterned for each pixel P1, P2, or P3. The low-reflection layer 300 may be patterned to correspond to the emission area EA of each pixel P1, P2, or P3. The area of the low-reflection layer 300 and an area of the emission area EA may be the same or the area of the low-reflection layer 300 may be greater than the emission area EA in a plan view.

The thin-film encapsulation layer 400 may be disposed on the low-reflection layer 300. The thin-film encapsulation layer 400 may include at least one inorganic layer and at least one organic layer. For example, the thin-film encapsulation layer 400 may include a first inorganic encapsulation layer 410, an organic encapsulation layer 420, and a second inorganic encapsulation layer 430 which are sequentially stacked.

The first and second inorganic encapsulation layers 410 and 430 may include an inorganic insulating material, such as SiO₂, SiNₓ, SiON, Al₂O₃, TiO₂, Ta₂O₅, HfO₂, ZnO₂ , the like, or a combination thereof. The first and second inorganic encapsulation layers 410 and 430 may each have a single layer or multiple layers.

The organic encapsulation layer 420 may relieve an internal stress of the first inorganic encapsulation layer 410 and/or the second inorganic encapsulation layer 430. The organic encapsulation layer 420 may include a polymer-based material or the like. The polymer-based material may include polyethylene terephthalate, polyethylene naphthalate, polycarbonate, polyimide, polyethylene sulfonate, polyoxymethylene, polyarylate, HMDSO, acrylic resin (e.g., PMMA, polyacrylic acid, or the like), the like, or a combination thereof.

The organic encapsulation layer 420 may be formed by spreading a material, which has flowability and includes monomers, and using heat or light, such as ultraviolet rays or the like, to combine the monomers to form polymers. In another embodiment, the organic encapsulation layer 420 may be formed by spreading a polymer material.

In case that cracks are generated in the thin-film encapsulation layer 400 because of the aforementioned multilayered structure, the thin-film encapsulation layer 400 may prevent such cracks from propagating between the first inorganic encapsulation layer 410 and the organic encapsulation layer 420 or between the organic encapsulation layer 420 and the second inorganic encapsulation layer 430. Thus, the formation of a path, through which external moisture, oxygen, or the like penetrates the display area DA, may be prevented or reduced.

In an embodiment, in case that the thin-film encapsulation layer 400 is disposed on the organic light-emitting diode OLED, the substrate 100 may include a polymer resin. However, the disclosure is not limited thereto.

The touch sensor layer 500 may be disposed on the thin-film encapsulation layer 400. The touch sensor layer 500 may include a first conductive layer MTL1, a first touch insulating layer 510, a second conductive layer MTL2, and a second touch insulating layer 520. The first conductive layer MTL1 may be disposed (e.g., disposed directly) on the thin-film encapsulation layer 400. For example, the first conductive layer MTL1 may be disposed (e.g., disposed directly) on the second inorganic encapsulation layer 430 of the thin-film encapsulation layer 400. However, the disclosure is not limited thereto.

Also, the touch sensor layer 500 may include an insulating layer (not shown) disposed between the first conductive layer MTL1 and the thin-film encapsulation layer 400. The insulating layer may be disposed on the second inorganic encapsulation layer 430 of the thin-film encapsulation layer 400 and may flatten a surface on which the first conductive layer MTL1 or the like are arranged. The first conductive layer MTL1 may be disposed (e.g., disposed directly) on the insulating layer. The insulating layer may include an inorganic insulating material, such as SiO₂, SiNₓ , SiON, the like, or a combination thereof. In another embodiment, the insulating layer may include an organic insulating material.

In an embodiment, the first touch insulating layer 510 may be disposed on the first conductive layer MTL1. The first touch insulating layer 510 may include an inorganic material or an organic material. For example, the first touch insulating layer 510 may include at least one material selected from the group consisting of SiNₓ , aluminum nitride (AlN), zirconium nitride (ZrN), titanium nitride (TiN), hafnium nitride (HfN), tantalum nitride (TaN), SiO₂, Al₂O₃, TiO₂, tin oxide (SnO₂), cerium oxide (CeO₂), and SiON. For example, the first touch insulating layer 510 may include at least one material selected from the group consisting of an acrylic resin, a methacrylic resin, polyisoprene, a vinyl-based resin, an epoxy-based resin, a urethane-based resin, a cellulose-based resin, and a perylene-based resin.

In an embodiment, the second conductive layer MTL2 may be disposed on the first touch insulating layer 510. The second conductive layer MTL2 may function as a sensor for sensing a touch input from a user. The first conductive layer MTL1 may function as a connecting portion for connecting, in a direction, the second conductive layer MTL2 that is patterned. In an embodiment, the first and second conductive layers MTL1 and MTL2 may function as sensors, and the first conductive layer MTL1 may be electrically connected to the second conductive layer MTL2 through a contact hole CH. As the first and second conductive layers MTL1 and MTL2 function as sensors, a resistance in the touch electrode may decrease, and the touch input from the user may be quickly sensed.

In an embodiment, the first and second conductive layers MTL1 and MTL2 may each have, for example, a mesh structure or the like, which allows light from the organic light-emitting diode OLED to pass through, and the first and second conductive layers MTL1 and MTL2 may be arranged not to overlap the emission area EA of the organic light-emitting diode OLED in a plan view.

The first and second conductive layers MTL1 and MTL2 may each include a metal layer or a transparent conductive layer. The metal layer may include Mo, Ag, Ti, Cu, Al, the like, or an alloy thereof. For example, the transparent conductive layer may include a transparent conductive oxide, such as ITO, IZO, ZnO, indium tin zinc oxide (ITZO), the like, or a combination thereof. For example, the transparent conductive layer may include a conductive polymer, such as PEDOT, metal nanowire, a carbon nanotube, graphene, or the like.

In an embodiment, the second touch insulating layer 520 may be disposed on the second conductive layer MTL2. The second touch insulating layer 520 may include an inorganic material or an organic material. For example, the second touch insulating layer 520 may include at least one material selected from the group consisting of SiNₓ , AlN, ZrN, TiN, HfN, TaN, SiO₂, Al₂O₃, TiO₂, SnO₂, CeO₂ , and SiON. For example, the second touch insulating layer 520 may include at least one material selected from the group consisting of an acrylic resin, a methacrylic resin, polyisoprene, a vinyl-based resin, an epoxy-based resin, a urethane-based resin, a cellulose-based resin, and a perylene-based resin.

The anti-reflection layer 600 may be disposed on the touch sensor layer 500. In an embodiment, the anti-reflection layer 600 may include a light-shielding layer 610 and a color filter layer 621. The anti-reflection layer 600 may further include an overcoat layer 625 disposed on the light-shielding layer 610 and the color filter layer 621.

The light-shielding layer 610 may include the openings 610OP in the emission areas EA. The openings 610OP may include a first opening 610OP1, a second opening 610OP2, and a third opening 610OP3 corresponding to the first to third organic light-emitting diodes OLED1, OLED2, and OLED3, respectively. The emission areas EA may be defined by the openings 209OP of the pixel-defining layer 209. In an embodiment, the opening 610OP of the light-shielding layer 610 may overlap the opening 209OP of the pixel-defining layer 209 in a plan view, and a width of the opening 610OP of the light-shielding layer 610 may be greater than a width of the opening 209OP of the pixel-defining layer 209 in a plan view.

A body portion of the light-shielding layer 610 excluding the opening 610OP may overlap a body portion of the pixel-defining layer 209 in a plan view. For example, the body portion of the light-shielding layer 610 may overlap only the body portion of the pixel-defining layer 209 in a plan view. The body portion of the light-shielding layer 610 may be a portion other than the opening 610OP and may have a volume (thickness) (e.g., a certain or selectable volume). The body portion of the pixel-defining layer 209 may be a portion other than the opening 209OP and may have a volume (e.g., a certain or selectable volume).

The light-shielding layer 610 may include a material that blocks light. For example, the light-shielding layer 610 may include an organic material with a high light absorption rate. The light-shielding layer 610 may include a black pigment, a dye, or the like. The light-shielding layer 610 may include a photosensitive organic material, for example, a coloring agent such as a pigment, a dye, or the like. The light-shielding layer 610 may not include a liquid-repellent material, silica particles, silica particles surface-treated with a liquid-repellent material, or the like. Because the light-shielding layer 610 does not include a liquid-repellent material, wetting may not occur. Also, because the light-shielding layer 610 does not include silica particles, a reliability problem resulting from silica particles may be prevented. The light-shielding layer 610 may have a single layer or multiple layers.

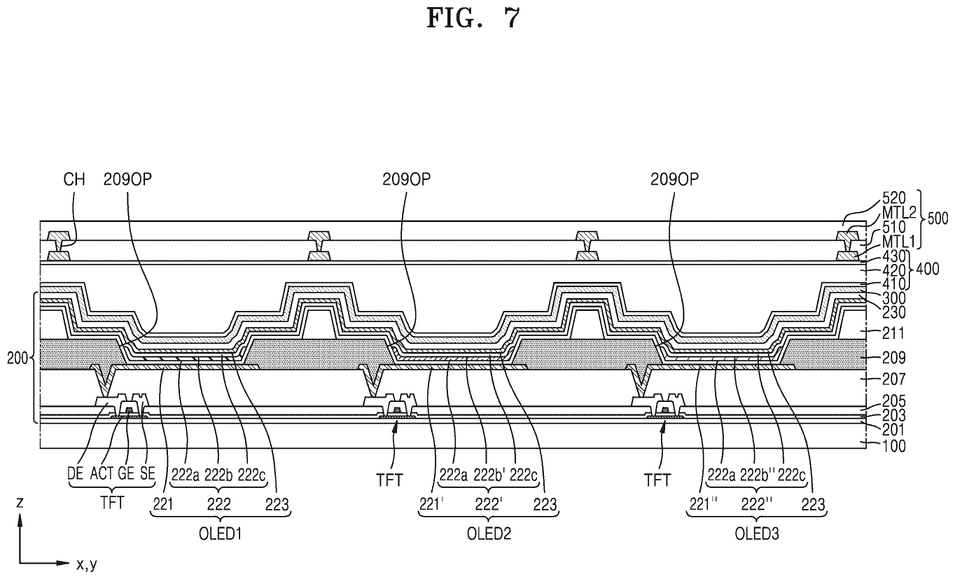

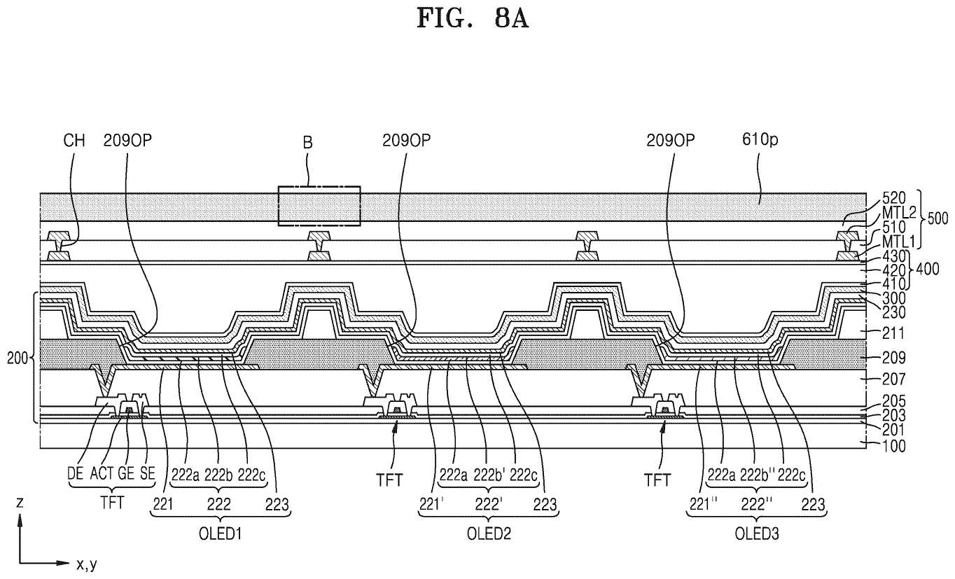

The light-shielding layer 610 may be formed by a manufacturing method described with reference to FIGS. 7 to 12. As shown in FIG. 5B, an upper surface 610u of the light-shielding layer 610 may have an uneven shape including multiple protrusions 610ut. The upper surface 610u of the light-shielding layer 610 may include the protrusions 610ut and multiple concave portions 610uc. The protrusions 610ut and the concave portions 610uc may be alternately arranged in a direction. As the upper surface 610u of the light-shielding layer 610 has an uneven shape, external light reflection may be reduced so that a visibility of the display device 1 may be improved.

In an embodiment, the protrusions 610ut may be irregularly or randomly arranged. For example, at least some of the protrusions 610ut may have different widths W. A width W of each protrusion 610ut may be a width of an uppermost surface or a minimum width of the protrusion 610ut.

In an embodiment, a gap (or distance) D between adjacent protrusions 610ut may be in a range of about 10 nm to about 60 nm. The gap (or the distance) D between adjacent protrusions 610ut may be a width of the concave portion 610uc. For example, the width D of the concave portion 610uc may be in a range of about 10 nm to about 60 nm.

The color filter layer 621 may include a first color filter 621a, a second color filter 621b, and a third color filter 621c which have different colors and respectively correspond to the first to third organic light-emitting diodes OLED1, OLED2, and OLED3.

In an embodiment, the first to third color filters 621a, 621b, and 621c may be arranged in the first to third openings 610OP1, 610OP2, and 610OP3 of the light-shielding layer 610, respectively. In an embodiment, the first to third color filters 621a, 621b, and 621c may have colors corresponding to light emitted from the first to third organic light-emitting diodes OLED1, OLED2, and OLED3. In an embodiment, in case that red light is emitted from the first organic light-emitting diode OLED1, the first color filter 621a may be a red color filter, in case that green light is emitted from the second organic light-emitting diode OLED2, the second color filter 621b may be a green color filter, and in case that blue light is emitted from the third organic light-emitting diode OLED3, the third color filter 621c may be a blue color filter. The light-shielding layer 610 may be arranged between neighboring (or adjacent) color filters 621a, 621b, and 621c and surround edges of each of the first to third pixels P1, P2, and P3 in a plan view.

The overcoat layer 625 may be disposed on the light-shielding layer 610 and the color filter layer 621. The overcoat layer 625 may be a colorless and light-transmissive layer that does not have a color in a visible band and may flatten an upper region (or the upper surface 610u) of the light-shielding layer 610 and an upper surface of the color filter layer 621. The overcoat layer 625 may include an achromatic and light-transmissive organic material, such as an acryl-based resin or the like, and may be covered by a window (not shown). The window may include a transparent (light-transmissive) material. For example, the window may include glass, a polymer, the like, or a combination thereof.

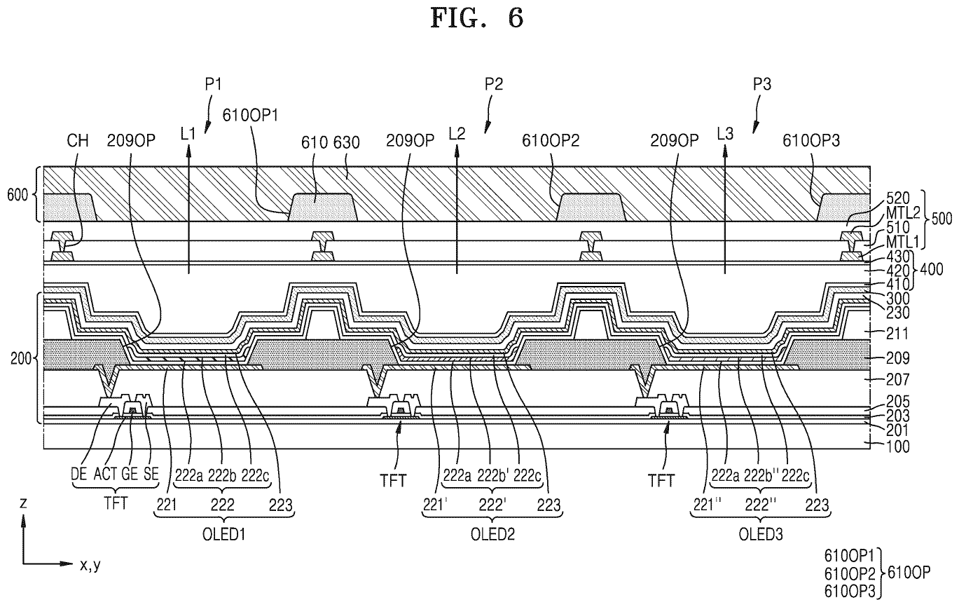

FIG. 6 is a schematic cross-sectional view of a portion of a display device 1 according to an embodiment. Descriptions that are the same as those given with reference to FIGS. 5A and 5B are omitted herein, and a difference between FIG.6 and FIGS. 5A and 5B is described.

Referring to FIG. 6, the anti-reflection layer 600 may not include the color filter layer 621 and may include a reflection control layer 630 that is integrally formed (or a single layer).

The reflection control layer 630 may selectively absorb light reflected from an inside of the display device 1 or light of a wavelength band (e.g., a certain or selectable wavelength band) that is incident from an outside of the display device 1. The reflection control layer 630 may include an organic material layer including a dye, a pigment, the like, or a combination thereof.

The reflection control layer 630 may include a Tetra aza porphyrin (TAP)-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, the like, or a combination thereof.

In an embodiment, a reflectivity measured on a surface of the reflection control layer 630 in a Specular Component Included (SCI) mode may be less than or equal to about 10%. For example, the reflection control layer 630 may absorb the external light reflection of the display device 1, and the visibility of the display device 1 may be improved.

The reflection control layer 630 may cover the light-shielding layer 610 and may be disposed on the touch sensor layer 500. The reflection control layer 630 may be formed in the entire display area DA and cover the light-shielding layer 610 and the first to third openings 610OP1, 610OP2, and 610OP3 of the light-shielding layer 610. As shown in FIG. 6, the reflection control layer 630 may be integrally formed (or the single layer) on the first to third organic light-emitting diodes OLED1, OLED2, and OLED3. For example, light L1 to L3 emitted from the first to third organic light-emitting diodes OLED1, OLED2, and OLED3 may pass through the reflection control layer 630.

In an embodiment, the reflection control layer 630 may have transmittance in a range of about 60% to about 80%. The light transmittance of the reflection control layer 630 may be adjusted according to the content of pigments and/or dyes included in the reflection control layer 630.

FIGS. 7 to 12 are schematic cross-sectional views illustrating a method of manufacturing a display device according to an embodiment. FIGS. 7 to 12 show the method of manufacturing the display device described with reference to FIGS. 5A and 5B. In the method of manufacturing the display device which is described with reference to FIGS. 7 to 12, descriptions of components corresponding to the components of the display device 1 of FIGS. 5A and 5B are omitted or simplified.

FIG. 7 shows a method of manufacturing the display device in an area corresponding to FIG. 5A.

Referring to FIG. 7, a lower structure including the substrate 100 may be formed. The lower structure may include the substrate 100, the display layer 200 on the substrate 100, the low-reflection layer 300 on the display layer 200, the thin-film encapsulation layer 400 on the low-reflection layer 300, and the touch sensor layer 500 on the thin-film encapsulation layer 400.

The substrate 100 may be formed, and the display layer 200 may be formed on the substrate 100. The display layer 200 may include an organic light-emitting diode (see, e.g., OLED of FIG. 2) as a display element, a thin-film transistor electrically connected to the organic light-emitting diode, and insulating layers arranged between the organic light-emitting diode and the thin-film transistor (see, e.g., T1 or T2 of FIG. 2). The display layer 200 may include a first light-emitting diode (e.g., a first organic light-emitting diode OLED1), a second light-emitting diode (e.g., a second organic light-emitting diode OLED2), and a third light-emitting diode (e.g., a third organic light-emitting diode OLED3) which emit light having different wavelengths and implement emission areas (see, e.g., EA of FIGS. 4A and/or 4B), respectively.

The low-reflection layer 300 may be formed on the display layer 200. The low-reflection layer 300 may include an inorganic material with low reflectivity. The low-reflection layer 300 may include, for example, a metal, a metal oxide, or the like. For example, the low-reflection layer 300 may include Yb, bismuth (Bi), cobalt (Co), Mo, Ti, Zr, Al, Cr, Nb, Pt, tungsten (W), In, Sn, iron (Fe), Ni, Ta, manganese (Mn), Zn, Ge, Ag, Mg, Au, Cu, Ca, the like, or a combination thereof. For example, the low-reflection layer 300 may include SiO₂, TiO₂ , ZrO₂, Ta₂O₅, HfO₂, Al₂O₃, ZnO, Y₂O₃, BeO, MgO, PbO₂, WO₃, SiNₓ, LiF, CaF₂, MgF₂ , CdS, the like, or a combination thereof.

The thin-film encapsulation layer 400 may be formed on the low-reflection layer 300. In an embodiment, the thin-film encapsulation layer 400 may include the first inorganic encapsulation layer 410, the organic encapsulation layer 420, and the second inorganic encapsulation layer 430 which are sequentially stacked.

The first and second inorganic encapsulation layers 410 and 430 may include an inorganic insulating material, such as SiO₂, SiNₓ, SiON, Al₂O₃, TiO₂, Ta₂O₅, HfO₂, ZnO₂ , the like, or a combination thereof. The first and second inorganic encapsulation layers 410 and 430 may each have a single layer or multiple layers.

The organic encapsulation layer 420 may relieve an internal stress of the first inorganic encapsulation layer 410 and/or the second inorganic encapsulation layer 430. The organic encapsulation layer 420 may include a polymer-based material or the like. For example, the organic encapsulation layer 420 may include polyethylene terephthalate, polyethylene naphthalate, polycarbonate, polyimide, polyethylene sulfonate, polyoxymethylene, polyarylate,

HMDSO, an acrylic resin (e.g., PMMA, polyacrylic acid, or the like), the like, or a combination thereof.

The organic encapsulation layer 420 may be formed by spreading a material, which has flowability and includes monomers, and using heat, light, such as ultraviolet rays or the like, or the like to combine the monomers to form polymers. In another embodiment, the organic encapsulation layer 420 may be formed by spreading a polymer material.

The touch sensor layer 500 may be formed on the thin-film encapsulation layer 400. The touch sensor layer 500 may include the first conductive layer MTL1, the first touch insulating layer 510, the second conductive layer MTL2, and the second touch insulating layer 520.

The first and second conductive layers MTL1 and MTL2 may each include a metal layer or a transparent conductive layer. The metal layer may include Mo, Ag, Ti, Cu, Al, the like, or an alloy thereof. For example, the transparent conductive layer may include a transparent conductive oxide, such as ITO, IZO, ZnO, ITZO, the like, or a combination thereof. For example, the transparent conductive layer may include a conductive polymer, such as PEDOT, metal nanowire, a carbon nanotube, graphene, or the like.

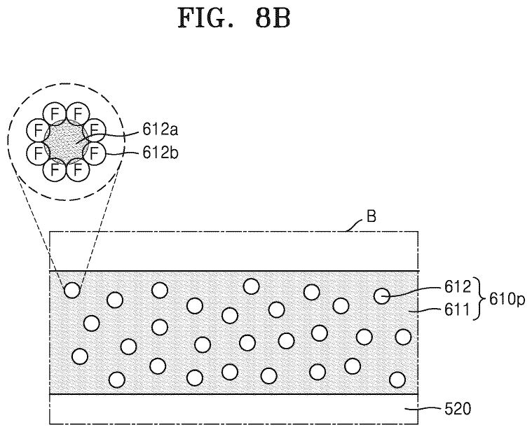

FIG. 8A shows the method of manufacturing the display device in an area corresponding to FIG. 5A. FIG. 8B shows enlarged region ‘B’ of FIG. 8A.

Referring to FIGS. 8A and 8B, an organic layer 610p may coat and be formed on the lower structure. The organic layer 610p may be formed on the touch sensor layer 500. As shown in FIG. 8B, the organic layer 610p may include a base resin 611 and the silica particles 612 surface-treated. The organic layer 610p may include a mixture of the base resin 611 and the surface-treated silica particles 612.

The base resin 611 may include a material that blocks light. For example, the base resin 611 may include an organic material with a high light absorption rate. The base resin 611 may include a black pigment, a dye, or the like. The base resin 611 may include a photosensitive organic material, for example, a coloring agent such as a pigment, a dye, or the like. In an embodiment, the base resin 611 may include a negative photosensitive organic material.

The surface-treated silica particles 612 may be formed by treating the surface of silica particle 612a with a liquid-repellent material 612b. The surface-treated silica particles 612 may have liquid repellency. The surface-treated silica particles 612 may be, for example, fluorine-treated silica particles with liquid repellency.

In an embodiment, the silica particle 612a may be colloidal silica. A size (or a diameter) of the surface-treated silica particle 612 may be in a range of, for example, about 10 nm to about 60 nm. The size (or the diameter) of the surface-treated silica particle 612 may be in a range of, for example, about 40 nm to about 60 nm. In an embodiment, the liquid-repellent material 612b may be a fluorine-based material or the like.

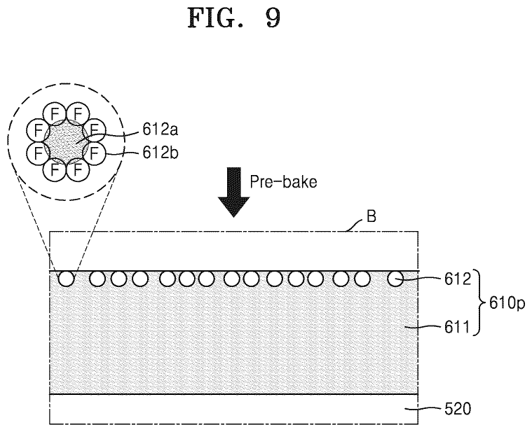

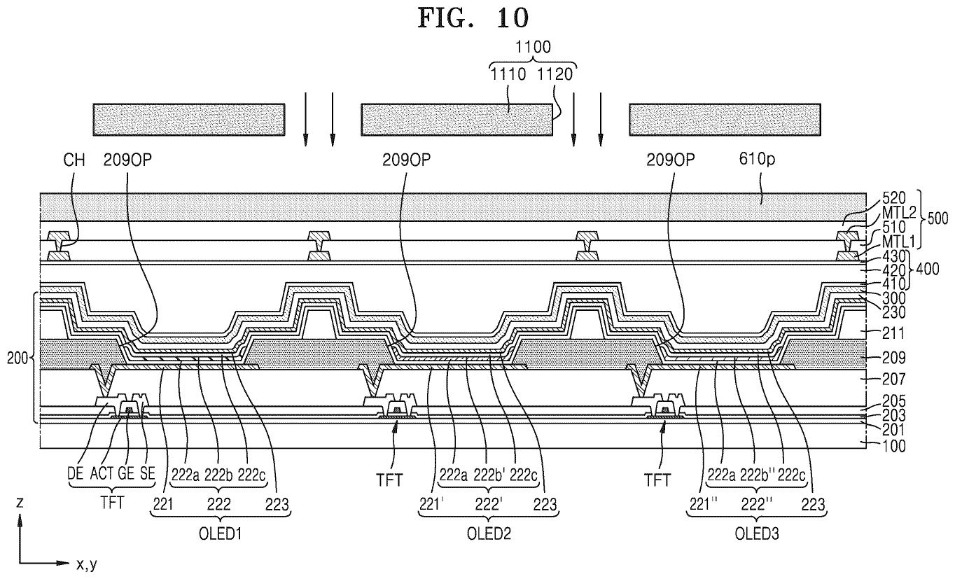

FIG. 9 shows the method of manufacturing the display device in an area corresponding to FIG. 8B.

Referring to FIG. 9, a pre-baking process (or a pre-baking operation), in which the organic layer 610p is heated, may be performed. In the pre-baking process, the organic layer 610p may be heated to a temperature (e.g., a certain or selectable temperature) to dry the base resin 611, and the base resin 611 may be attached to the lower structure. In the pre-baking process, the organic layer 610p may be heated to a temperature (e.g., a certain or selectable temperature), and the surface-treated silica particles 612 may be separated from the base resin 611 and moved to an upper portion (or an upper surface) of the organic layer 610p. Because the surface-treated silica particles 612 are liquid-repellent, in case that heat is applied, the silica particles 612 may be separated from the base resin 611 and moved to the upper portion (or the upper surface) of the organic layer 610p (e.g., the base resin 611). For example, in the pre-baking process, the base resin 611 and the surface-treated silica particles 612 may be phase-separated. As the surface-treated silica particles 612 are moved to the surface of the organic layer 610p in the pre-baking process, the silica particles 612 may be irregularly or randomly arranged.

The pre-baking process may be performed, for example, for a period in a range of about 100 seconds to about 200 seconds at a temperature in a range of about 80° C. to about 90° C., but the disclosure is not limited thereto.

FIG. 10 shows the method of manufacturing the display device in an area corresponding to FIG. 5A.

Referring to FIG. 10, an exposure process (or an exposure operation) may be performed, the exposure process being a process in which a light is irradiated onto the organic layer 610p.

The exposure process may be performed using an exposure mask 1100 including a light-shielding portion 1110 and an opening 1120. The light may be irradiated onto the organic layer 610p through the opening 1120 of the exposure mask 1100. In an embodiment, the exposure mask 1100 may be arranged such that the opening 1120 overlaps an area corresponding to the light-shielding layer 610 in a plan view described with reference to FIG. 5A. In an embodiment, the light may be irradiated onto an area, in which the light-shielding layer 610 is formed, through subsequent processes. Because the surface-treated silica particles 612 do not include a photoreactor, the silica particles 612 may not be chemically or physically mixed with other materials in the exposure process.

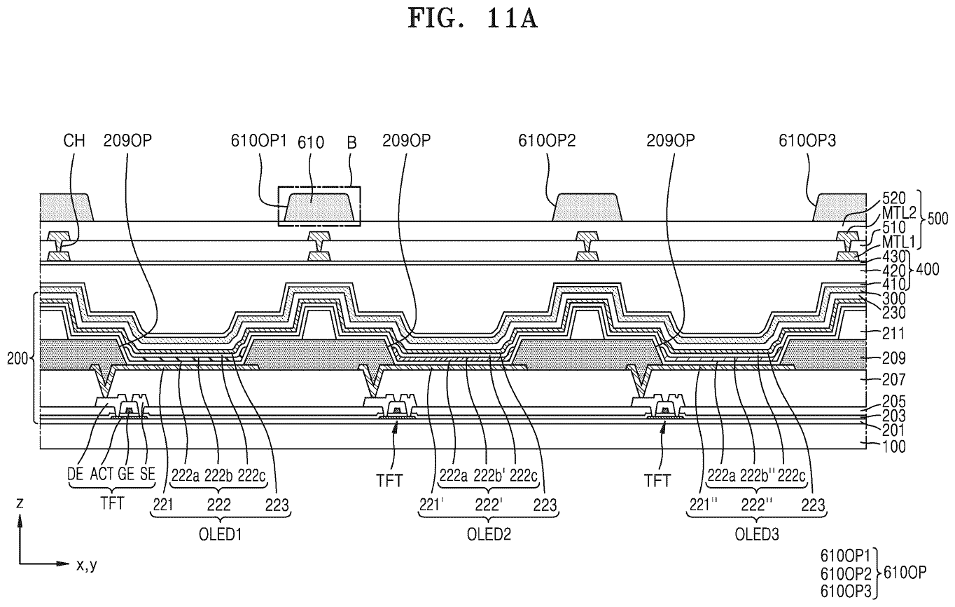

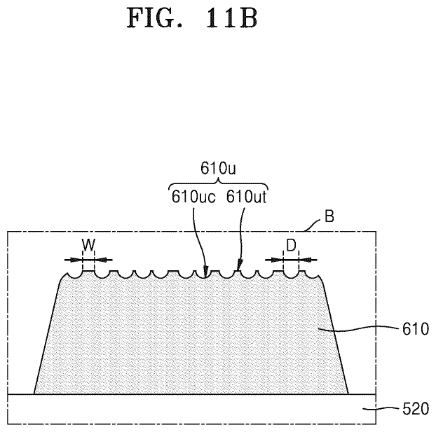

FIG. 11A shows the method of manufacturing the display device in an area corresponding to FIG. 5A. FIG. 11B shows enlarged region ‘B’ of FIG. 11A.

Referring to FIGS. 11A and 11B, a development process (or a development operation) of developing a pattern from the organic layer (see, e.g., 610p of FIG. 10), to which the light is irradiated during the exposure process, may be performed. Because of the development process, a portion (e.g., at least a portion) of the organic layer 610p may be removed, and the light-shielding layer 610 may be formed. As the portion of the organic layer 610p is removed, the light-shielding layer 610 including the openings 610OP may be formed. The openings 610OP may include the first to third openings 610OP1, 610OP2, and 610OP3 that respectively correspond to the first to third organic light-emitting diodes OLED1, OLED2, and OLED3.

The development process may further include a rinse process (or a rinse operation) of removing a developer used during the development process. In case that the development process and the rinse process are performed, the surface-treated silica particles (see, e.g., 612 of FIG. 9) included in the organic layer 610p may be removed. Because the surface-treated silica particles 612 do not include a photoreactor, the silica particles 612 may not be chemically or physically mixed with other materials in the exposure process. Accordingly, the surface-treated silica particles 612 arranged on the surface of the organic layer 610p may be removed (e.g., entirely removed) in the development process and the rinse process. For example, the light-shielding layer 610 may not include the liquid-repellent material, the silica particles, or the silica particles surface-treated with the liquid-repellent material. Because the light-shielding layer 610 does not include a liquid-repellent material, wetting may not occur. Also, because the light-shielding layer 610 does not include silica particles, a reliability problem resulting from the silica particles may be prevented.

As the surface-treated silica particles 612 are removed, the upper surface 610u of the light-shielding layer 610 may have an uneven shape including the protrusions 610ut. The upper surface 610u of the light-shielding layer 610 may include the protrusions 610ut and the concave portions 610uc. The protrusions 610ut and the concave portions 610uc may be alternately arranged.

The concave portions 610uc may be portions formed as the surface-treated silica particles 612 are removed. Therefore, a width D of the concave portion 610uc may be in a range of, for example, about 10 nm to about 60 nm. The width D of the concave portion 610uc may be a gap (or distance) between adjacent ones of the protrusions 610ut. The gap (or the distance) D between the adjacent ones of the protrusions 610ut may be in a range of, for example, about 10 nm to about 60 nm.

Because the surface-treated silica particles 612 are irregularly arranged on the upper surface of the organic layer 610p, the protrusions 610ut, which are formed through the removal of the surface-treated silica particles 612, may be irregularly arranged. For example, at least some of the protrusions 610ut may have different widths W.

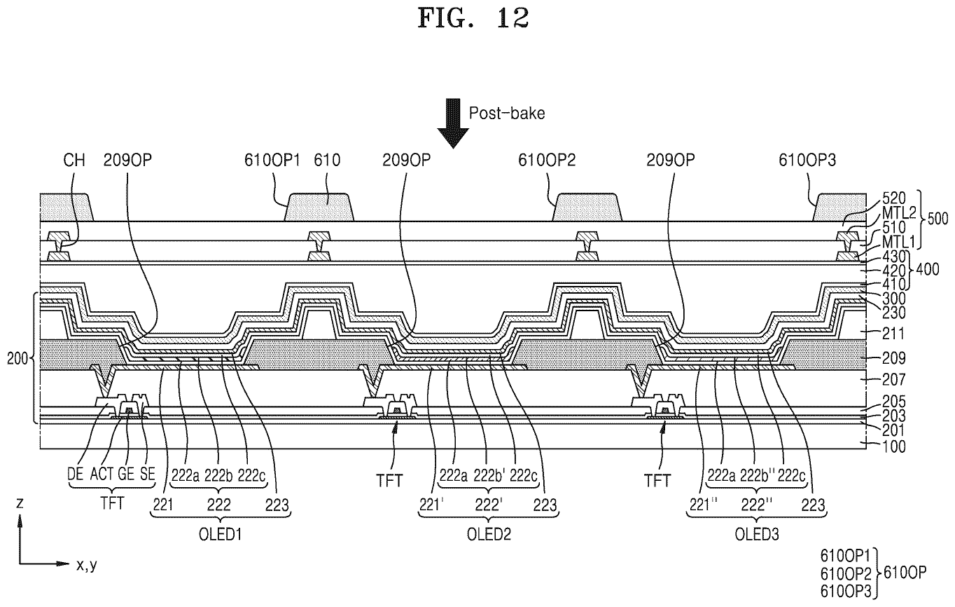

FIG. 12 shows the method of manufacturing the display device in an area corresponding to FIG. 5A.

Referring to FIG. 12, a post-baking process (or a post-baking operation), in which the light-shielding layer 610 is heated, may be performed. In the post-baking process, the light-shielding layer 610 may be dried, and the adhesion of organic materials may increase. The post-baking process may be performed, for example, for a period in a range of about 50 minutes to about 70 minutes at a temperature in a range of about 80° C. to about 90° C.

Referring back to FIG. 5A, the color filter layer 621 may be further formed on the light-shielding layer 610 formed according to the method of manufacturing the display device which is described with reference to FIGS. 7 and 12. The color filter layer 621 may include the first to third color filters 621a, 621b, and 621c which have different colors and respectively correspond to the first to third organic light-emitting diodes OLED1, OLED2, and OLED3.

In an embodiment, the first to third color filters 621a, 621b, and 621c may be formed in the first to third openings 610OP1, 610OP2, and 610OP3 of the light-shielding layer 610, respectively. In an embodiment, the first to third color filters 621a, 621b, and 621c may have colors corresponding to light emitted from the first to third organic light-emitting diodes OLED1, OLED2, and OLED3. In an embodiment, in case that red light is emitted from the first organic light-emitting diode OLED1, the first color filter 621a may be a red color filter, in case that green light is emitted from the second organic light-emitting diode OLED2, the second color filter 621b may be a green color filter, and in case that blue light is emitted from the third organic light-emitting diode OLED3, the third color filter 621c may be a blue color filter. The light-shielding layer 610 may be arranged between neighboring (or adjacent) color filters 621a, 621b, and 621c and surround the edges of each of the first to third pixels P1, P2, and P3 in a plan view.

In another embodiment, referring back to FIG. 6, the reflection control layer 630 may be formed on the light-shielding layer 610 according to the method of manufacturing the display device which is described with reference to FIGS. 7 to 12.

The reflection control layer 630 may include a TAP-based compound, a porphyrin-based compound, a metal porphyrin-based compound, an oxazine-based compound, a squarylium-based compound, a triarylmethane-based compound, a polymethine-based compound, an anthraquinone-based compound, a phthalocyanine-based compound, an azo-based compound, a perylene-based compound, a xanthene-based compound, a diimmonium-based compound, a dipyrromethene-based compound, a cyanine-based compound, the like, or a combination thereof.

In an embodiment, the reflectivity measured on a surface of the reflection control layer 630 in an SCI mode may be less than or equal to about 10%. For example, the reflection control layer 630 may absorb the external light reflection of the display device 1, and the visibility of the display device 1 may be improved.

The reflection control layer 630 may cover the light-shielding layer 610 and may be formed on the touch sensor layer 500. The reflection control layer 630 may be formed in the entire display area DA and cover the light-shielding layer 610 and the first to third openings 610OP1, 610OP2, and 610OP3 of the light-shielding layer 610. As shown in FIG. 6, the reflection control layer 630 may be integrally formed (or the single layer) on the first to third organic light-emitting diodes OLED1, OLED2 and OLED3.

The method of manufacturing the display device may include an operation of forming a lower structure including the substrate 100, an operation of forming the organic layer 610p on the lower structure, a pre-baking operation, an exposure operation, a development operation, and a post-baking operation. According to embodiments, as the light-shielding layer 610 is formed using the organic layer 610p including the silica particles 612 surface-treated with the liquid-repellent material, the light-shielding layer 610 having an uneven shape on the surface (e.g., the protrusions 610ut) of the light-shielding layer 610 may be formed without performing an additional process that is different from the process of forming the light-shielding layer 610. Therefore, manufacturing costs and time may be reduced.

According to embodiments, a display device 1 with improved visibility may be implemented by reducing external light reflection. However, the scope of the disclosure is not limited by such effects.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
forming a lower structure comprising a substrate;
forming, on the lower structure, an organic layer comprising:
a base resin; and
silica particles surface-treated with a liquid-repellent material;
performing a pre-baking process by heating the organic layer;
performing an exposure process by irradiating light onto the organic layer; and
performing a development process to form a light-shielding layer by removing a portion of the organic layer,
wherein, in the development process, the silica particles surface-treated with the liquid-repellent material are removed from the organic layer.

2. The method of claim 1, wherein, in the pre-baking process, the silica particles surface-treated with the liquid-repellent material are moved to an upper portion of the organic layer.

3. The method of claim 1, wherein an upper surface of the light-shielding layer comprises a plurality of protrusions.

4. The method of claim 3, wherein the plurality of protrusions of the light-shielding layer are irregularly arranged.

5. The method of claim 3, wherein at least some of the plurality of protrusions of the light-shielding layer have different widths in a direction.

6. The method of claim 3, wherein a gap between adjacent ones of the plurality of protrusions of the light-shielding layer is in a range of about 10 nm to about 60 nm.

7. The method of claim 1, wherein sizes of the silica particles surface-treated with the liquid-repellent material are in a range of about 10 nm to about 60 nm.

8. The method of claim 1, wherein the liquid-repellent material comprises a fluorine-based material.

9. The method of claim 1, wherein the base resin comprises a photosensitive organic material and a coloring agent.

10. The method of claim 1, wherein the base resin comprises a negative photosensitive organic material.

11. The method of claim 1, wherein the pre-baking process is performed for a period in a range of about 100 seconds to about 200 seconds at a temperature in a range of about 80° C. to about 90° C.

12. The method of claim 1, further comprising:
performing a post-baking process by heating the light-shielding layer.

13. The method of claim 12, wherein the post-baking process is performed for a period in a range of about 50 minutes to about 70 minutes at a temperature in a range of about 80° C. to about 90° C.

14. The method of claim 1, wherein the lower structure comprises:
a display layer disposed on the substrate and comprising:
a light-emitting diode; and
a thin-film transistor electrically connected to the light-emitting diode;
a low-reflection layer disposed on the display layer and comprising an inorganic material;
a thin-film encapsulation layer disposed on the low-reflection layer; and
a touch sensor layer disposed on the thin-film encapsulation layer and comprising a conductive layer.

15. The method of claim 1, further comprising:
forming a color filter layer on the light-shielding layer.

16. A display device comprising:
a first light-emitting diode, a second light-emitting diode, and a third light-emitting diode, which are disposed on a substrate and implement emission areas by emitting light of different wavelengths;
a low-reflection layer disposed on the first light-emitting diode, the second light-emitting diode, and the third light-emitting diode and comprising an inorganic material; and
a light-shielding layer disposed on the low-reflection layer and comprising openings corresponding to the emission areas, wherein
an upper surface of the light-shielding layer has an uneven shape comprising a plurality of protrusions, and the plurality of protrusions are irregularly arranged.

17. The display device of claim 16, wherein at least some of the plurality of protrusions have different widths in a direction.

18. The display device of claim 16, wherein a gap between adjacent ones of the plurality of protrusions is in a range of about 10 nm to about 60 nm.

19. The display device of claim 16, further comprising:
a color filter layer comprising a first color filter, a second color filter, and a third color filter, which respectively correspond to the first light-emitting diode, the second light-emitting diode, and the third light-emitting diode and are arranged in the openings of the light-shielding layer.

20. The display device of claim 16, further comprising:
a reflection control layer covering the light-shielding layer and the openings of the light-shielding layer and integrally formed on the first light-emitting diode, the second light-emitting diode, and the third light-emitting diode.
